(19) United States
(12) Patent Application Publication
(10) Pub. No.: US 2019/0206713 A1
(43) Pub. Date: Jul. 4, 2019

(54) METHOD FOR PRODUCING A SEMICONDUCTOR DEVICE, SEMICONDUCTOR DEVICE AND SUPPORT

(71) Applicant: Fraunhofer-Gesellschaft zur Forderung der angewandten Forschung e.V., Munich (DE)

(72) Inventors: Richard Reiner, Freiburg (DE); Thomas Gerrer, Freiburg (DE); Dirk Meder, Freiburg (DE); Beatrix Weiss, Offenburg (DE); Patrick Waltereit, Freiburg (DE)

(73) Assignee: Fraunhofer-Gesellschaft zur Forderung der angewandten Forschung e.V., Munich (DE)

(21) Appl. No.: 16/224,017

(22) Filed: Dec. 18, 2018

(30) Foreign Application Priority Data
Jan. 2, 2018 (DE) 10 2018 200 020.4

(51) Int. Cl. H01L 21/683; H01L 21/02; H01L 23/13; H01L 23/538; H01L 23/373; H01L 23/15; H01L 29/20

(52) U.S. Cl. CPC H01L 21/6835; H01L 21/0254; H01L 23/13; H01L 21/02458; H01L 21/02381; H01L 23/5384; H01L 2221/68363; H01L 23/3731; H01L 23/5389; H01L 23/5386; H01L 23/15; H01L 29/2003; H01L 2221/68381; H01L 23/3732

(57) ABSTRACT

A method for producing a semiconductor device is provided. A growth substrate having a first side and an opposite second side is provided. At least one electronic component is produced by depositing and/or structuring at least one layer on the first side of the growth substrate, said layer containing or consisting of at least one compound semiconductor. The first side of the electronic component that is opposite the first side of the growth substrate is connected to a support. The growth substrate is removed. The support has at least one feed-through and/or at least one conductor track, which is connected to at least one terminal contact of the electronic component. Alternatively or in addition, a semiconductor device produced in this way and a support having such a semiconductor device may be provided.

### CROSS-REFERENCE TO RELATED APPLICATIONS

This application claims priority under 35 USC § 119 to German Patent Application No. 10 2018 200 020.4, filed Jan. 2, 2018, which is hereby incorporated by reference.

### TECHNICAL FIELD

The invention relates to a method for producing a semiconductor device, comprising the following steps: providing a growth substrate having a first side and an opposite second side, producing at least one electronic component by depositing and/or structuring at least one layer on the first side of the growth substrate, said layer containing or consisting of a compound semiconductor, bonding the first side of the electronic component opposite the first side of the growth substrate to a support, and removing the growth substrate. The invention also relates to such a semiconductor device and a support having such a semiconductor device.

### BRIEF DESCRIPTION OF THE DRAWINGS

The embodiments may be better understood with reference to the following drawings and description. The components in the figures are not necessarily to scale. Moreover, in the figures, like-referenced numerals designate corresponding parts throughout the different views.

FIGS. 1 to 4 show method steps of a first embodiment of the invention;

FIGS. 5 to 8 show method steps of a second embodiment of the invention;

FIGS. 9 to 11 show method steps of a third embodiment of the invention; and

FIG. 12 shows the breakdown field strength of a semiconductor device according to the invention compared to known semiconductor devices.

### DETAILED DESCRIPTION

P. Srivastava et al: “Silicon Substrate Removal of GaN DHFETs for Enhanced (>1100 V) Breakdown Voltage”, IEEE ELECTRON DEVICE LETTERS, vol. 31, no. 8, August 2010 discloses to produce an electronic component by depositing and structuring at least one layer on a silicon wafer, said layer containing a group III nitride. Furthermore, it is known that the dielectric strength of such components is not limited by the group III nitride used as the active semiconductor material but that voltage breakdowns occur in the vertical direction across the silicon wafer.

In order to solve this problem, the prior art proposes removing the electronic component from the silicon wafer and applying it to a sapphire support. However, the sapphire support used in the prior art has the disadvantage that it is not available over a large area and does not allow electrical contacting of the electronic component.

Based on the prior art, the invention is thus based on the object of providing a semiconductor device with a high breakdown voltage and a method for the production thereof that is simpler and cheaper than some of the prior art.

The invention proposes a method for producing a semiconductor device, said method containing at least one layer which contains or consists of at least one compound semiconductor. If a plurality of said layers are deposited on top of one another, superlattices and/or semiconductor heterostructures can be generated, which provide an increased charge carrier mobility and/or an increased charge carrier concentration and/or an increased breakdown field strength compared to homogeneous materials. A plurality of layers or even a single layer can be structured in a way known per se by masking and etching in order to create different functional areas. It is thus possible to produce field effect transistors, light emitting diodes, superluminescent diodes, Schottky diodes, semiconductor lasers or other optoelectronic components.

In some embodiments, the compound semiconductor can be selected from AlₓGa₁₋ₓN and/or In_{y}Ga_{1-y}N and/or In_{y}Ga_{1-y}N and/or Sc_{z}In_{1-z}N and/or InP and/or GaAs and/or GaSb. The parameters x, y, and z can vary and take values between 0 and 1 or between 0.08 and 0.85 or between 0.1 and 0.75.

The electronic component is produced by depositing or structuring at least one layer containing a compound semiconductor on a growth substrate. In some embodiments of the invention, the growth substrate contains silicon and/or SiC and/or Al₂O₃ and/or GaAs and/or InP. Optionally, intermediate layers can be arranged between the growth substrate and the compound semiconductor to improve adhesion and/or reduce lattice mismatch and/or etch stop layers. The production of an electronic component of the type described is generally familiar to a person skilled in the art.

Such components have the fundamental disadvantage that the breakdown field strength, and thus the achievable operating voltage, is limited by the material used as growth substrate. While the compound semiconductor used as an active semiconductor material has a relatively high breakdown field strength due to its large band gap, breakthroughs can occur via the growth substrate when critical field strengths are exceeded.

However, due to the existing lattice mismatch between the growth substrate and the group III nitrides deposited thereon, the layers forming the electronic component exhibit high mechanical stresses and/or low mechanical strengths, so that, when the growth substrate is removed, cracks often appear which irreparably damage the electronic component and render it unusable.

Therefore the invention proposes to apply the electronic component with its first side opposite the growth substrate to a support and then to remove the growth substrate. In this case, the electronic component is mechanically stabilized by the support to prevent damage. The electronic component can be attached to the support, for example, by gluing or soldering. Bonding can be done e.g. with a phenolic resin or an epoxy resin or another thermosetting plastics.

The invention proposes to use a printed circuit board as a support, which, in addition to the electronic component, has at least one feedthrough and/or at least one conductor track. In this way, it is easily possible not only to mechanically fix, and thus stabilize, the electronic component but also to electrically contact it and connect it to other components to form an electronic circuit. These additional components can be surface-mounted or also wired electronic components, which are known per se. In addition, the common materials used for printed circuit boards, such as hard paper (FR1, FR2, FR3), glass fiber-reinforced plastics (FR4, FR5), polytetrafluoroethylene or also ceramics, are widely spread and available at low cost. Neither is the raw material particularly expensive, nor is the processing particularly complex and possible on widely used machines for the production of printed circuit boards. Completely by surprise, it was recognized that such a circuit board is sufficient for stabilization and that expensive supports made of sapphire are not required to ensure reliable operation of the component.

According to the invention, it was recognized that a commercially available printed circuit board is suitable as a carrier substrate for electronic components and provides sufficient mechanical stability so that the growth substrate can be removed. This can cause the breakdown voltage of an electronic component, such as a diode, transistor, IGBT or diode, to rise to more than 600 V or more than 1200 V or more than 1600 V. The voltage of an electronic component, such as a diode, a transistor, an IGBT or a diode, can also rise to more than 600 V or more than 1200 V.

In some embodiments of the invention, the support can have a recess in which the electronic component is received. This allows the electronic component to be inserted flush with the surface of the circuit board used as a support. In other embodiments of the invention, the circuit board used as the support can be completely closed so as to protect the electronic component from damage caused by environmental or mechanical influences.

In some embodiments of the invention, the support can have a thickness of about 0.5 mm to about 5 mm for this purpose. In other embodiments of the invention, the support can have a thickness of approximately 1.5 mm to approximately 3 mm. In some embodiments, the support can contain a plurality of individual layers, in each of which at least one electrical conductor track is arranged. This also allows complex wiring patterns and/or comparatively large conductor cross-sections for high current carrying capacity to be realized.

In some embodiments of the invention, a second side of the electronic component can be connected to a substrate after the removal of the growth substrate. In some embodiments of the invention, such a substrate can be selected from ceramics or diamond. In some embodiments of the invention, the substrate can be multi-layered and, for example, can itself carry electrical conductor tracks on an insulating material. The substrate can promote the heat dissipation of the electronic component and/or further increase the electrical breakdown field strength. In some embodiments of the invention, the substrate can have a dielectric constant of about 3.0 to about 10, thus improving the high-frequency properties of the electronic component.

In some embodiments of the invention, the growth substrate can be removed by wet or dry chemical etching. For example, hydrofluoric acid or sulfur hexafluoride can be used as etching agent. In some embodiments of the invention, the growth substrate can be removed by machining, such as grinding or micro milling. In yet other embodiments of the invention, the growth substrate can first be thinned by machining, for example to a thickness of about 50 μm to about 150 μm. The remaining growth substrate can then be removed by wet or dry chemical etching.

In some embodiments of the invention, a buffer layer can first be deposited on the growth substrate when the electronic component is produced. In some embodiments, this buffer layer can contain or consist of AlₓGa₁₋ₓN. In some embodiments of the invention, x can be selected from the range of 1 to 0.9 or 1 to 0.95. This buffer layer can reduce the lattice mismatch of subsequent layers. At the same time, this buffer layer can be used as an etch stop layer if an etchant is used that attacks the material of the growth substrate but does not attack the material of the buffer layer or etch stop layer, or if the etchant has at least a reduced etch rate compared to the material of the etch stop layer. In this way, the growth substrate can be reliably removed without damaging the electronic component.

In some embodiments of the invention, part of the compound semiconductor produced on the growth substrate can also be removed, for example intermediate layers for adhesion and/or reduction of lattice mismatches. This can further improve the electrical properties of the component on the support.

In some embodiments of the invention, a protective varnish can be applied to the support prior to the removal of the growth substrate in order to prevent or reduce the undesired etching of the support in this way. This ensures that only the growth substrate is reliably removed from the electronic component without attacking or damaging the remaining support of the semiconductor component according to the invention.

In the following, the invention will be explained in more detail by means of drawings and embodiments without limiting the general concept of the invention, wherein

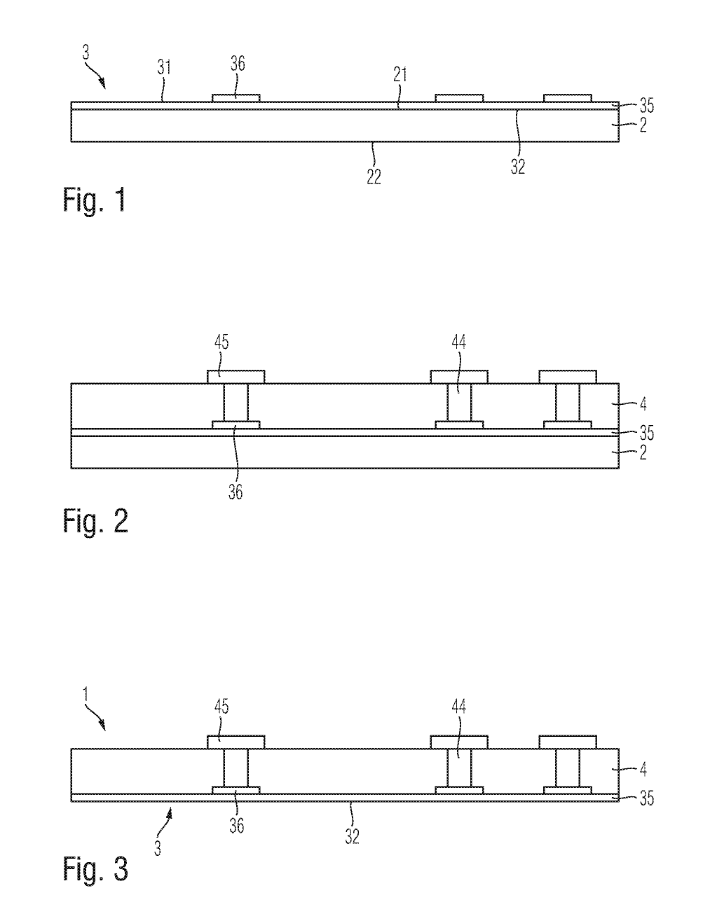

FIGS. 1 to 4 show method steps of a first embodiment of the invention.

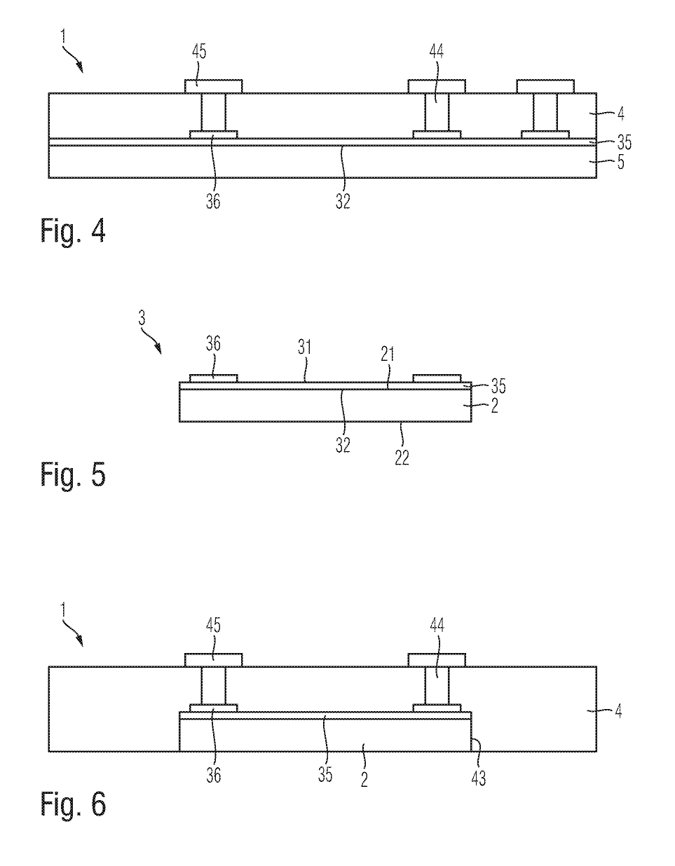

FIGS. 5 to 8 show method steps of a second embodiment of the invention.

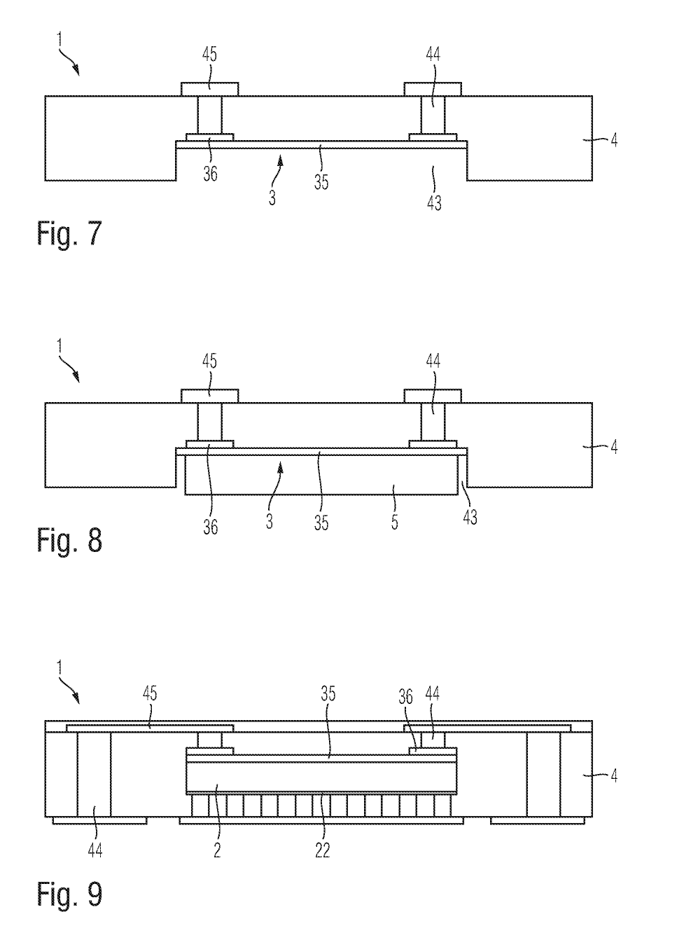

FIGS. 9 to 11 show method steps of a third embodiment of the invention.

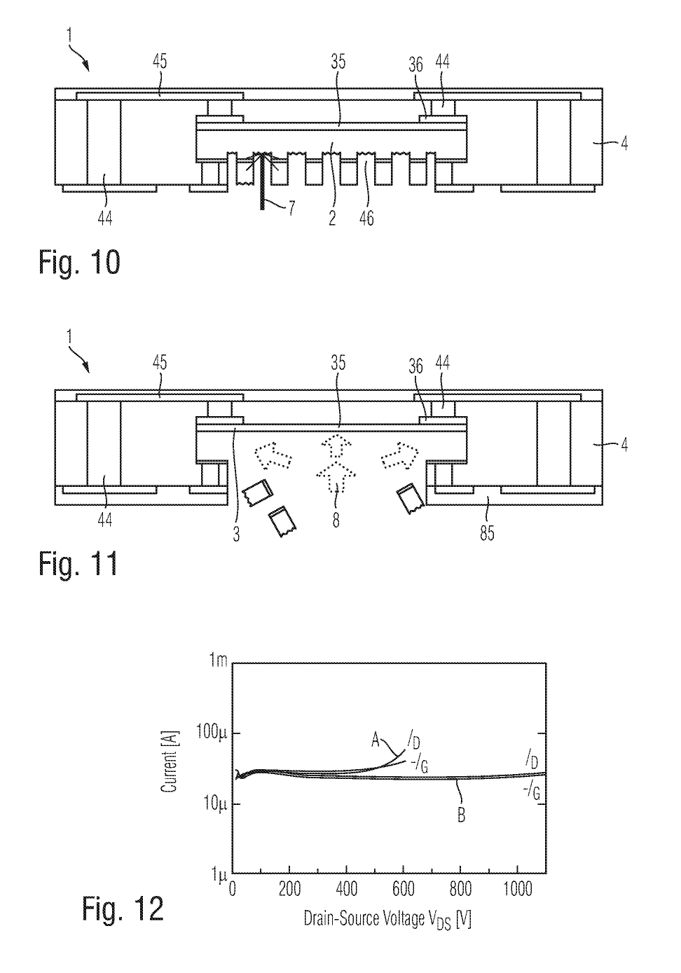

FIG. 12 shows the breakdown field strength of a semiconductor device according to the invention compared to known semiconductor devices.

FIGS. 1 to 4 explain a first embodiment of the invention. FIG. 1 shows an electronic component known per se, which contains at least one layer 35, which contains or consists of e.g. AlₓGa₁₋ₓN. Layer 35 is deposited on a growth substrate 2, which contains or consists of silicon, for example. However, a person skilled in the art is aware that in other embodiments of the invention other compound semiconductors and/or other growth substrates can be used as well. The invention does not teach the use of a certain component as a solution principle.

The growth substrate 2 has a first side 21 and an opposite second side 22. The layer 35 is deposited from the gas phase in a manner known per se on the first side 21, e.g. by MOCVD, MOVPE or other methods known per se. As a result, the second side 32 of layer 35 is connected to the first side 21 of growth substrate 2. In order to produce electronic components, the layer 35 can consist of a plurality of individual layers, which themselves can have different compositions. For example, the parameter x can be selected differently in different individual layers of the layer 35 and assume values between 0 and 1, so that individual layers from binary ternary group III nitride compounds can be produced. This can be used to create adhesion-promoting or insulating intermediate layers or semiconductor heterostructures. In addition, the layers can be structured by masking and etching to thus produce semiconductor devices, such as diodes, field-effect transistors or optoelectronic components, such as light-emitting diodes or semiconductor lasers. As far as a layer 35 is mentioned below, this includes complex layer structures comprising of a plurality of individual layers with or without lateral structuring.

At least one terminal contact 36, which is arranged in the form of a structured metal layer on the first side 31 of the layer 35, serves to electrically contact the at least one electronic component 3 in the layer 35.

These components known per se have the disadvantage that the breakdown field strength, and thus the maximum operating voltage, is limited by the breakdown field strength of growth substrate 2. On the other hand, due to the existing lattice mismatch with respect to the growth substrate 2, high mechanical stresses can prevail in the layer 35, said stresses leading to the fracture of the layer 35 when the growth substrate 2 is detached. As a result, electronic components implemented in the layer 35 are damaged and rendered unusable.

As shown in FIG. 2, it is proposed according to the invention to bring the first side 31 of the layer 35 forming the electronic component 3 into contact with a support 4. In some embodiments of the invention, a frictional connection is created between the support 4 and the electronic component 3, for example by gluing. Such an adhesive bond can be made e.g. with a phenolic resin or an epoxy resin.

The support 4 itself can be a printed circuit board or contain a printed circuit board. Such a circuit board can consist of e.g. a glass fiber-reinforced plastic material, a hard paper, ceramics and/or polytetrafluoroethylene or can contain these materials. In addition, the printed circuit board contains occasionally conductor tracks 45, which are attached to at least one side of the support 4 in the form of a metallization of a partial area. The conductor tracks 45 can be produced e.g. by structuring a copper coating, by punched grids or lead frames or by wire-laying. In addition, the support 4 shown in FIG. 2 contains vias 44, which are connected to the terminal contacts 36 of the electronic component 3. The vias 44 can be produced in a manner known per se by making a through-hole in the support 4, followed by metallizing, wherein the metallization fills the through-hole either completely or partially. The connection between the via 44 and the terminal contact 36 can be made e.g. by soldering or galvanic contacting. Occasionally, it is also possible to use an adhesive bond with an electrically conductive adhesive.

The support 4 shown in FIG. 2 in the form of a printed circuit board thus allows the electronic component 3 to be both mechanically fastened and electrically contacted. In addition, further electronic components, such as capacitors, resistors, semiconductor devices or plug-in connectors, can be arranged on the support 4 in a manner known per se. These components can be surface-mounted as SMD components or also be mounted on the support 4 in wired fashion.

FIG. 3 shows the semiconductor device 1 according to the invention after removing the growth substrate 2. For this purpose, the growth substrate can be machined, e.g. by grinding or milling. Alternatively or additionally, the growth substrate 2 can also be treated by wet or dry chemical etching, e.g. by means of hydrofluoric acid (HF) or sulfur hexafluoride (SF₆). In some embodiments of the invention, the growth substrate 2 can first be thinned by machining, for example from an initial thickness of about 600 μm to about 700 μm to a final thickness of about 100 μm. The residues remaining after this method step can be treated by wet or dry chemical etching. This allows, on the one hand, a rapid removal of a large part of the growth substrate 2 by machining and subsequently a gentle removal of the remaining material without affecting the layer 35.

If an etchant is used for wet or dry chemical etching that selectively attacks the growth substrate 2 but leaves the material of the layer 35 unaffected, the etching step automatically stops when the layer 35 is reached without further attack of this layer by the etchant. Damage to the electronic component 3 can thus be avoided.

According to the invention, it was discovered that mechanical stresses can be absorbed by connecting the electronic component 3 to the support 4, so that damage to the electronic component 3 is avoided even after the removal of the growth substrate 2. According to the invention, it was found that no expensive and comparatively stable material, such as sapphire or diamond, has to be used for this purpose. Completely by surprise, an ordinary circuit board made of fiber-reinforced thermosetting plastics or thermoplastic is fully sufficient for this purpose. After removing the growth substrate 2, the electrical breakdown field strength is no longer limited by the breakdown field strength of the silicon, so that the operating voltage of the electronic component 3 can be increased.

FIG. 4 shows an optional method step of the present invention. According to FIG. 4, the growth substrate can be replaced by a substrate 5, which has a beneficial effect on the properties of the electronic component 3. For example, the substrate 5 can contain or consist of diamond or ceramics or a metal or an alloy. This can, for example, facilitate heat dissipation or improve the high-frequency properties or further increase the breakdown field strength or dielectric strength of the electronic component 3. Since the layer 35 is not deposited on the substrate 5, the substrate 5 can be selected from a plurality of possible materials. It is not necessary to select the substrate from materials on which the group III nitrides according to the invention can be deposited from the gas phase. Therefore, the electronic component 3 can be advantageously produced on a low-cost growth substrate 2 and, in addition to the support 4, can be connected during operation to a further substrate 5, which improves the electrical and/or thermal properties.

FIGS. 5 to 8 describe a second embodiment of the invention. Equal components of the invention are provided with the same reference sign, so that the following description is limited to the essential differences.

FIG. 5 again shows an electronic component 3 known per se, which consists of a layer or a layer system 35 consisting of or containing binary or ternary group III nitrides. The layer or layer system 35 is deposited on a growth substrate 2 from the gas phase, as described above. If a plurality of components is produced during production, these can optionally be separated.

FIG. 6 shows how to connect the electronic component 3 to a support 4. In contrast to the first embodiment described above, the support 4 has a recess 43 in which the electronic component 3 with the growth substrate 2 is inserted.

In this case, too, the terminal contacts 36 of the electronic component 3 can be connected to vias 44, which extend from one side of the support 4 that is opposite the recess into the recess 43. The vias 44 can be connected to conductor tracks 45.

As shown in FIG. 7, the growth substrate 2 is subsequently removed by machining or etching as described above. In this way, the electronic component 3 is arranged inside the support 4 and protected from mechanical damage.

FIG. 8 shows an optional fourth method step. As already described above by means of the first embodiment, a substrate 5 can be applied to the second side 32 of the layer 35 of electronic component 3 that is exposed after the removal of the growth substrate 2. The substrate 5 can be used for heat dissipation, electrical insulation and/or improvement of the high-frequency properties of the electronic component 3. For this purpose, the substrate 5 can contain or consist of a metal, ceramics or diamond. In some embodiments of the invention, the substrate 5 can be or contain a sealing compound of a polymer or thermosetting plastics. This allows the recess 43 to be filled so that the electronic component 3 inside the support 4 is protected against mechanical damage.

FIGS. 9 to 11 explain a third embodiment of the invention. As can be seen from FIG. 9, an electronic component 3 with the growth substrate 2 and the layer 35 arranged thereon are inserted, according to the third embodiment, into a recess of a support 4, as described above. The support 4 can in particular be a multilayer board, which is composed of a plurality of individual layers, each of which has structured metal layers as an electrical conductor track.

Subsequently, the support 4 is also closed on its underside, so that the electronic component 3 with growth substrate 2 is embedded in the support 4. The increased stability resulting from the growth substrate 2 prevents damage to the layer 35 and the electronic component 3. In some embodiments of the invention, the recess 43 can be closed by autoclaving a plurality of prepregs, i.e. fiber reinforcement mats pre-treated with partially cured resin and cured under pressure and temperature, wherein the individual layers are joined.

After embedding the electronic component 3 and the growth substrate 2 and optionally carrying out electrical or electronic function tests, the support 4 is opened on its underside. This can be done by machining, for example with a drill or a milling cutter. In other embodiments of the invention, a laser 7 can be used, which partially removes the material of the support 4 and creates recesses 46 in the support 4. In some embodiments of the invention, the support 4 can be mechanically stabilized before the recesses 46 are created, for example by inserting it into a housing. This prevents damage to the layer 35 after the removal of growth substrate 2.

In the final method step, which is shown in FIG. 11, the growth substrate 2 is removed by the action of an etchant 8. An optional etching mask 85 can be applied to prevent damage to the support 4 or conductor tracks 45.

After removing the growth substrate 2, an optional substrate 5 can be applied, as described above using the first and second embodiments. In other embodiments of the invention, this step can be omitted.

FIG. 12 shows the current flowing through a field effect transistor on the ordinate against the drain source voltage on the abscissa. The measurement curves A are recorded before the removal of growth substrate 2 and the measurement curves B are recorded after the removal of the growth substrate.

FIG. 12 shows that the current increases from about 600 V if growth substrate 2 is present, since the breakthrough field strength of the growth substrate is reached. In contrast, curve B shows that the leakage currents remain stable up to a voltage of 1100 V after the growth substrate 2 was removed. Therefore, FIG. 12 shows that the dielectric strength of the electronic component 3 can be increased by removing the growth substrate 2 and at the same time the layer 35 is stabilized by the support 4 in such a way that the electronic component 3 is not destroyed by mechanical stresses.

It goes without saying that the invention is not limited to the illustrated embodiments. Therefore, the above description should not be considered limiting but explanatory. The following claims should be understood in such a way that a stated feature is present in at least one embodiment of the invention. This does not exclude the presence of further features. If the claims and the above description define “first” and “second” embodiments, this designation serves to distinguish between two similar embodiments without determining a ranking order.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

1. A method for producing a semiconductor device, the method comprising:
providing a growth substrate having a first side and an opposite second side;
producing at least one electronic component by depositing and/or structuring at least one layer on the first side of the growth substrate, the at least one layer containing or consisting of at least one compound semiconductor;
connecting the first side of the electronic component that is opposite the first side of the growth substrate to a support; and
removing the growth substrate, wherein the support has at least one feed-through and/or at least one conductor track, which is connected to at least one terminal contact of the electronic component.

2. The method of claim 1, wherein the support contains or consists of glass fiber-reinforced plastics, ceramics, and/or polytetrafluoroethylene.

3. The method of claim 1, wherein the compound semiconductor is selected from AlₓGa₁₋ₓN, In_{y}Ga_{1-y}N, Sc_{z}In_{1-z}N, InP, GaAs, and/or GaSb.

4. The method of claim 1, wherein the support has a recess, in which the electronic component is received.

5. The method of claim 1, wherein further components are on and/or in the support.

6. The method of claim 1, wherein the support has a thickness that is in a range of about 0.5 mm to about 5 mm and/or wherein the support contains a plurality of individual layers, on each of which at least one electrical conductor track is arranged.

7. The method of claim 1, wherein the electronic component has a breakdown voltage of more than 600 V.

8. The method of claim 1, wherein the electronic component has a breakdown voltage of more than 1200 V.

9. The method of claim 1, wherein the electronic component has a breakdown voltage of more than 1600 V.

10. The method of claim 1 further comprising connecting a second side of the electronic component to a substrate after removing the growth substrate.

11. The method of claim 10, wherein the substrate is selected from ceramics or diamond.

12. The method of claim 1, wherein the growth substrate is removed by wet or dry chemical etching and/or by machining.

13. The method of claim 12 further comprising arranging an etch stop layer between the growth substrate and the electronic component.

14. A semiconductor device obtainable by depositing and/or structuring at least one layer on the first side of a growth substrate, said layer containing or consisting of at least one compound semiconductor and a first side of the semiconductor device is connected to a support, wherein the support has at least one feed-through and/or at least one conductor track, which is connected to at least one terminal contact of the electronic component and the growth substrate has been removed.

15. The semiconductor device of claim 14, wherein the support contains or consists of glass fiber-reinforced plastics, ceramics, and/or polytetrafluoroethylene.

16. The semiconductor device of claim 14, wherein the support comprises a recess configured to receive the electronic component.

17. The semiconductor device of claim 14, wherein further components are on and/or in the support.

18. The semiconductor device of claim 14, wherein a second side of the electronic component is connected to a substrate containing diamond or ceramics.
